(19) United States
(12) Patent Application Publication
(10) Pub. No.: US 2022/0013334 A1
(43) Pub. Date: Jan. 13, 2022

(54) DEVICE FOR COATING CONTAINERS WITH A BARRIER LAYER, AND METHOD FOR HEATING A CONTAINER

(71) Applicant: KHS CORPOPLAST GMBH, Hamburg (DE)

(72) Inventors: Sebastian KYTZIA, Todesfelde (DE); Joachim KONRAD, Duesseldorf (DE)

(21) Appl. No.: 17/253,365

(22) PCT Filed: Jun. 19, 2019
(86) PCT No.: PCT/EP2019/066112

§ 371 Date: May 14, 2021

(30) Foreign Application Priority Data
Jun. 20, 2018 (DE) 10 2018 114 776.7

(51) Int. Cl. H01J 37/32; C23C 16/40

(52) U.S. Cl. CPC H01J 37/32477; H01J 37/32449; C23C 16/0209; H01J 37/32394; C23C 16/401; H01J 37/3222

(57) ABSTRACT

The present invention relates to a device for coating containers with a barrier layer having at least one plasma chamber, which encloses at least one treatment space, in which at least one container with a container interior can be inserted and can be positioned on the treatment space, wherein a gas lance is provided which can be introduced into the container interior and which further acts as microwave antenna, with the plasma chamber being designed to be capable at least of partial evacuation and being designed to fill the container interior at least partially with a plasma and a process gas. The device is designed such that the container can be preheated by means of a plasma, more particularly by means of a microwave plasma, using a noble gas which can be introduced into the container interior through the gas lance.

### FIELD OF INVENTION

The present invention relates to a device for coating containers with a barrier layer having at least one plasma chamber, and a method for heating a container by means of such a device.

### BACKGROUND OF RELATED ART

Such devices are used for example in the vacuum control of a silicon oxide coating process, in particular in the plasma-enhanced CVD coating of plastic containers, such as e.g. PET bottles. Barrier systems for various application formats are produced with such a coating. O2, CO2 and H2O barriers are preferably applied to PET bottles. This method takes place under vacuum. As PET containers with high thermal stability are becoming established on the market (for example for pasta sauces), new method steps in the deposition of barriers on pre-heated containers (substrate) present themselves. As a result better barrier properties with respect to gas permeability and expansion properties (>3%) can be achieved. Coating lines which accomplish this are known from DE 10 2016 105 548 A1, for example.

The general trend towards coating (very) light containers, such as PET bottles, requires that this bottle has a defined temperature on entry into the coating line. This was recognized in EP 0 821 079 B1. An inlet cooling before the coating line is therefore necessary in order to ensure a high-quality process for depositing silicon oxide.

From WO 98/40531 A1 it is also known to heat the PET bottles before entry into the coating line. Heating the PET bottles in the coating line by means of a heater recessed in the wall of a holder for the PET bottle is known from WO 2012/122559 A2.

### SUMMARY

The object of the present invention is to improve the barrier properties of the coating on the inside wall of the coated container and to allow for better prerequisites for the hot-filling process of the containers.

This object is achieved according to the invention by a device with the features of claim 1. The device for coating containers with a barrier layer has at least one plasma chamber, which includes at least one treatment space, and in which at least one container with a container interior can be inserted and positioned on the treatment space. A gas lance is present which can be introduced into the container interior and which furthermore acts as microwave antenna. The plasma chamber is formed to be capable of at least partial evacuation and is set up to fill the container interior at least partially with a plasma and a process gas. According to the invention it is provided that the device is formed such that a pre-heating of the container can be carried out by means of a plasma, in particular by means of a microwave plasma, using a noble gas, wherein the noble gas can be introduced into the container interior via the gas lance. Through the use of a plasma to heat the containers, the energy used in the deposition of the barrier can be increased significantly and the barrier layer then has fewer defects, which leads to a better barrier efficiency. A PET container, in particular a PET bottle, is preferably used as container. The container can also be made of another plastic, in particular PP, PE or POC.

The advantage of introducing the gas lance into the container interior and then using it as microwave antenna is that
the heating power coupled into the container interior can be controlled by varying the gas lance length,
the microwave is coupled into the valve manifold through the gas lance, with the result that an ignition of the heating plasma is made possible over a higher pressure range, enabling different heating intensities for the plasma to be achieved.
the microwave is coupled into the valve manifold through the gas lance, with the result that an ignition of the heating plasma is made possible for different gases.

An advantageous development of the invention provides that the noble gas is taken from the group Ne, Ar, Kr and/or Xe; preferably only Ar, optionally with residual air, is used as noble gas. Through the use of one of the named noble gases, no chemical changes result on the surface of the containers during the heating thereof. The use of pure Ar is the least expensive.

A further advantageous development of the invention provides that a heating tunnel is present before the device in the path for conveying the container into it. An enclosed air conveying in the transfer region of a block machine is thereby possible. Through the heating carried out in the heating tunnel a pre-expansion of the container is achieved. The subsequent coating is then effected on the expanded container, routinely at a container temperature in the range of 80-200° C. If the temperature of the coated container lies above the temperature of the filling material which is introduced into it, only a shrinkage process of the container takes place, which is less destructive with respect to the coating than an expansion process.

A further advantageous development of the invention provides that the plasma chamber is part of a plasma wheel, which has a plurality of such plasma chambers. The throughput of the containers to be coated can be increased significantly thereby.

The object is also achieved by a method with the features of claim 6. Such a method for heating a container is carried out by means of a device according to the invention explained above. According to the invention it is provided that the heating is effected by means of a plasma in a pressure range of 1-25 mbar, preferably in a pressure range of 1-5 mbar or in a pressure range of 15-25 mbar, using a noble gas. It is thereby possible to introduce a well-defined power and thus quantity of heat into the container, which has the result that the container temperature reached can thereby be set precisely to a desired temperature, at which the following processes, in particular during the application of the barrier layer, achieve particularly good results. If the method is carried out in the lower of the two named pressure ranges, a gentler treatment of the inner surface of the container than at a higher pressure is made possible, but this takes up more time. If the method is carried out in the higher of the two named pressure ranges, a stronger ion bombardment of the surface of the container takes place, which leads to a faster heating of the inner surface of the container. In both pressure ranges, a better surface modification results compared with the state of the art, which leads to better results with respect to heating, contact angle, surface roughness and pre-treatment. Containers made of PET are preferably used.

An advantageous development of the method according to the invention provides that the noble gas is taken from the group Ne, Ar, Kr and/or Xe; preferably only Ar, optionally with residual air, is used as noble gas. Here, the advantages already explained above for the device in respect of the noble gases used result.

A further advantageous development of the method according to the invention provides that the average power introduced by the plasma lies in the range of 80-670 W, in particular is 500 W, and/or the pulse power lies in the range of 250-2000 W, in particular is 1500 W. With a higher average power in the barrier layer, which leads to fewer defects, a thinner-walled barrier layer can be allowed to grow and a higher flexibility with the same gas permeability can thus be achieved.

A further advantageous development of the method according to the invention provides that the temperature of the container lies in the range of 30-75° C., preferably in the range of 33-70° C. and particularly preferably is 50° C. It has been shown in coating experiments that the named temperature range produces improved barrier properties after exposure. Due to the heating of the substrate, the kinetic energy of the atoms in the layer-forming process is higher, with the result that an ordered silicon oxide layer with fewer defects forms. This means that the barrier is better.

A further advantageous development of the method according to the invention provides that the heating has a cycle duration in the range of 0-5000 ms, in particular 3000 ms, with a pulse duration in the range of 1-20 ms, preferably 10 ms, and a pause duration in the range of 10-50 ms, preferably 20 ms.

A further advantageous development of the method according to the invention provides that before this heating a pre-heating of the container to a temperature in the range of 80-200° C. takes place, in particular in a heating tunnel, which is arranged in an inlet to the plasma chamber. Here, the advantages already explained above for the device in respect of the heating tunnel result.

A further advantageous development of the method according to the invention provides that following the method steps a coating of the container interior with a barrier layer and then a coating with silicon oxide is effected and subsequently the container is hot-filled with a filling material which is hotter than 50° C., preferably hotter than 70° C., particularly preferably hotter than 90° C. As a result, for example pasta sauces or other filling materials to be bottled at such high temperatures can also be poured into the coated containers.

All features of the advantageous developments specified in the dependent claims belong to the invention both separately in each case individually and in any desired combinations.

Further details and advantages of the invention are explained in more detail with reference to an embodiment example represented in the drawings.

### BRIEF DESCRIPTION OF THE DRAWINGS

There are shown in:

FIG. 1 the dependence of the temperature of a bottle on the plasma power;

FIG. 2 the dependence of the reflectance on the plasma power;

FIG. 3 the dependence of the temperature of a bottle on the pressure of the plasma gas;

FIG. 4 the dependence of the plasma power or the reflectance on the pressure of the plasma gas;

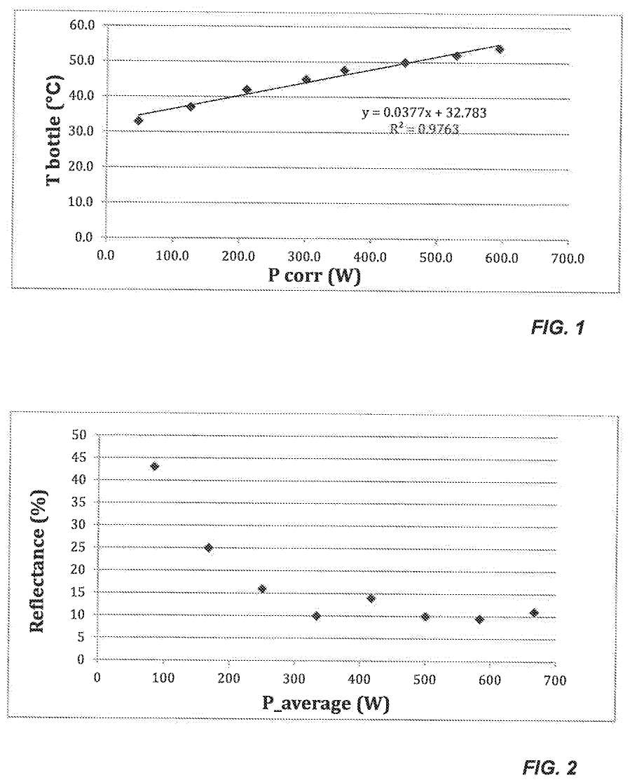

Tab. 1 the experimental results on which FIGS. 1 and 2 are based, and

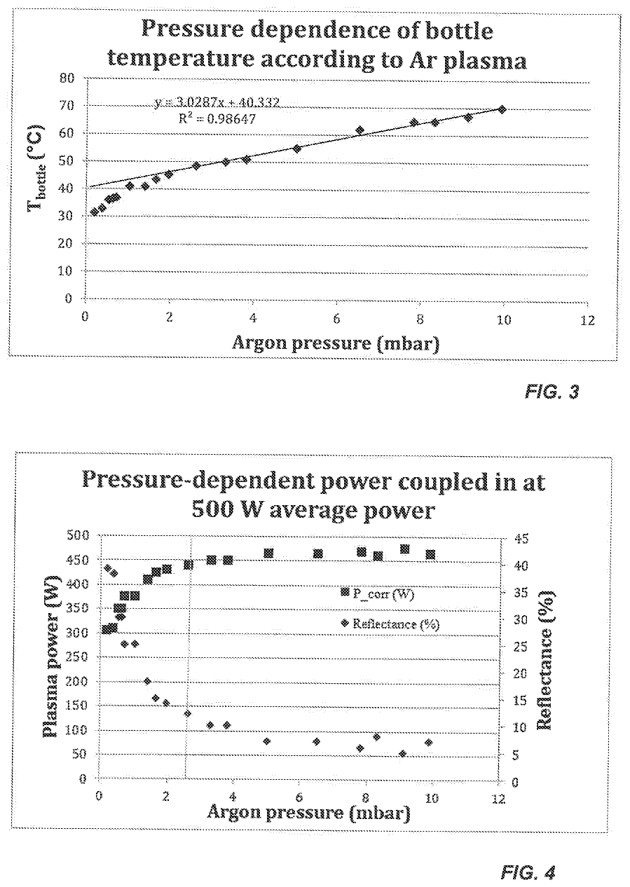

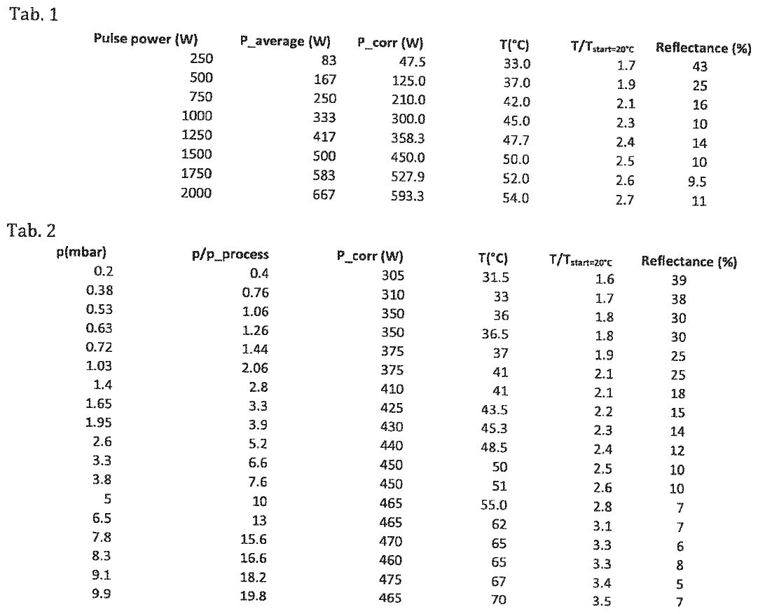

Tab. 2 the experimental results on which FIGS. 3 and 4 are based.

In a method according to the invention carried out with a device according to the invention, the measurement results listed in Tab. 1 and 2 were found.

### DETAILED DESCRIPTION

A coating line in the form of a plasma wheel was used, by means of which a barrier layer made of oxygen can be applied to a PET container in a plasma chamber, after a silicon oxide deposition process has taken place. Then a hot filling of the PET container with a filling material hotter than 90° C. can be carried out. The pre-heating of the PET container was effected by means of a plasma made of pure Ar (with a proportion of residual air), which was ignited by means of a microwave unit.

In the experiments which are documented in Tab. 1, a power variation of the argon plasma was carried out at a pressure pargon=3.3 mbar. The starting temperature of the PET containers before the experiment was 20° C. and is denoted Tstart=20° C. A duty cycle of 33% was present. By duty cycle is meant the ratio of the pulse_on times to the pulse_on+pulse_off times—it could also be called pulse-pause ratio. The relevant further parameters were: Ar flow rate=560 sccm; total time of the heating phase t_plasma=3000 ms; pulse_on time t_pulse=10 ms; pulse_off time t_pause=20 ms. The specified pulse-pause ratio was chosen in order to obtain controllability of the temperature distribution. Bottles made of PET which have a volume of 500 ml and a weight of 29 g were used as PET containers.

The specified measured temperature was always measured approx. 5 s after extinguishment of the plasma, since the casing for the vacuum must first be removed in order to be able to take a temperature measurement on the PET container by means of the infrared sensor present.

In addition to the pulse power (P_pulse), Tab. 1 also gives the average power (P_average) of the energy input (in Watts in each case) into the PET containers due to the Ar plasma. The adjusted power P_corr (also specified in Watts) results from the product of the pulse power with the duty cycle and the factor (1—reflectance). Tab. 1 also gives the reflectance. By reflectance is meant the proportion of the magnetron's coupled-in power which is not absorbed by the plasma; this proportion is reflected by the PET container and directed via a circulator into a water load, where it is converted into heat. Moreover, Tab. 1 also gives the ratio of the final temperature of the PET container and its starting temperature.

In FIG. 1, the results of the final temperature of the PET containers are represented over the adjusted power. A straight line, which has an offset of 32.783 and a slope of 0.0377 with R2=0.9763, can be drawn through the measurement points as a very good approximation. By R2 is meant the regression coefficient, which specifies a coefficient of determination and describes how well the measurement points fit on a straight line. At values of R2>0.95, a linear relationship is assumed. The heating of the PET containers is thus effected linearly with the plasma power introduced. The temperature difference from T_room=20° C. results through the additional energy input by the ignition pulse or auxiliary discharges.

The dependence of the reflectance on the average power P_average is represented in FIG. 2.

Tab. 2 documents the results of experiments in which a pressure variation of the Ar plasma was carried out with a constant average power P_average=500 W. In addition to the columns already known from Tab. 1 for the absolute value of the temperature of the PET container T (in ° C.) and its ratio to the starting temperature T/Tstart=20° C. and the reflectance, the absolute value of the pressure p (in mbar) of the Ar gas, as well as the quotient of this absolute value and the p_process (by this is meant the pressure in the PET container which is used for normalization, since pressure data cannot be read off directly), which was 0.5 mbar, are also listed.

In FIG. 3, the pressure dependence of the bottle temperature Tbottle with respect to the Ar pressure is represented using the results from Tab. 2. The bottle temperature Tbottle increases as the pressure increases, since at higher pressures the number of collisions with the wall of the PET container increases and a stronger flow of heat from the hot Ar plasma to the cold wall can thus take place. Above an Ar pressure of approx. 2 mbar a linear dependence results as a good approximation, which can be described by a straight line with an offset of 40.332 and a slope of 3.0287 with R2=0.98647. The deviation from the linear behaviour below 2 mbar results due to increasing reflectances at low pressures. This relationship between reflectance and Ar pressure can be seen in FIG. 4, where the results from Tab. 2 are displayed. There, it is the graph which is represented by the rhombuses.

In FIG. 4, the dependence of the adjusted plasma power P_corr on the Ar pressure is also represented by means of squares.

A particularly effective heating of the PET container is achieved by generating an Ar plasma in a pressure range of 15-25 mbar (P1 pressure range). The higher pressure causes a stronger ion bombardment on the surface of the PET container. A rapid strong heating of the inner surfaces with corresponding surface modification (heating, contact angle, surface roughness, pre-treatment) is possible.

A medium heating of the PET container can be achieved by igniting an Ar plasma in a pressure range of 1-5 mbar (P2 pressure range). This pressure range makes a gentler treatment of the surface possible, which, however, takes up more time. A medium heating of the inner surface with corresponding surface modification (heating, contact angle, surface roughness, pre-treatment) can be realized.

The process optimization can in particular be effected through a further heating tunnel before the coating line (enclosed air conveying, transfer region block machine), if it is only a question of heating the PET container (pre-expansion). The heating expands the PET container, with the result that the coating is effected on an expanded PET container (80-200° C.). The barrier layer on its inside wall no longer expands, but rather only contracts in a cooling process following the filling of the PET container. Shrinkage is less destructive for the coating than expansion.

This is particularly advantageous in the case of a hot filling, which follows the heating and coating of the PET container—e.g. wherein a pasteurized pasta sauce is poured in. The PET container cannot be expanded further here. Only when it is cooled does the PET container contract, with the result that only shrinkage acts on the coating. As stated above, shrinkage is less destructive for the coating than expansion. Better barrier efficiencies can thus be achieved through this procedure, since fewer stress factors occur.

For thermally stable PET containers, other temperatures can be used in the process control, which stress the coating less and thus lead to a better barrier performance (gas-tightness, flexibility). Moreover, different pre-treatments and surface modifications can be carried out, which makes an optimization possible for the deposition of layers on specific products.

The advantages of the invention can be summarized as follows.

Through the heating or thermal stability of the material, the following can be achieved:

The energy (microwave energy) used in the deposition of the barrier can be increased significantly. As a result the layer can grow with fewer defects and the barrier efficiency can be improved. With a higher average power in the barrier layer (fewer defects), a thinner-walled barrier layer can be allowed to grow and a higher flexibility, with the same gas permeability, can thus be achieved.

The enhanced process steps and method possibilities result in the following advantages:

More gas-tight or more gas-impermeable barrier layers with shorter or unchanged coating times; higher flexibility (in the region of >3%) of the barrier layers; modification of the surface properties of the PET container for better growth of the coating compound (adhesion).

1. A device for coating containers with a barrier layer having at least one plasma chamber, which includes at least one treatment space, and in which at least one container with a container interior can be inserted and positioned on the treatment space, wherein a gas lance is present which can be introduced into the container interior and which furthermore acts as microwave antenna, wherein the plasma chamber is formed to be capable of at least partial evacuation and is set up to fill the container interior at least partially with a plasma and a process gas, wherein the device is formed such that a pre-heating of the container can be carried out by means of a plasma, in particular by means of a microwave plasma, using a noble gas which can be introduced into the container interior via the gas lance.

2. The device according to claim 1, wherein the noble gas is taken from the group Ne, Ar, Kr and/or Xe; preferably only Ar, optionally with residual air, is used as noble gas.

3. The device according to claim 1, wherein a heating tunnel is present before the device in the path for conveying the container into it.

4. The device according to claim 1, wherein the container is a plastic container, in particular made of PP, PE, PET or POC.

5. The device according to claim 1, wherein the plasma chamber is part of a plasma wheel, which has a plurality of such plasma chambers.

6. A Method for heating a container by means of a device according to claim 1, wherein the heating is effected by means of a plasma in a pressure range of 1-25 mbar, preferably in a pressure range of 1-5 mbar or in a pressure range of 15-25 mbar, using a noble gas.

7. The Method according to claim 6, wherein the noble gas is taken from the group Ne, Ar, Kr and/or Xe; preferably only Ar, optionally with residual air, is used as noble gas.

8. The Method according to claim 6, wherein an average power introduced by the plasma lies in the range of 80-670 W, in particular is 500 W, and/or the pulse power lies in the range of 250-2000 W, in particular is 1500 W.

9. The Method according to claim 6, wherein a temperature of the container lies in the range of 30-75° C., preferably in the range of 33-70° C. and particularly preferably is 50° C.

10. The Method according to claim 6, wherein the heating has a cycle duration in the range of 0-5000 ms, in particular 3000 ms, with a pulse duration in the range of 1-20 ms, preferably 10 ms, and a pause duration in the range of 10-50 ms, preferably 20 ms.

11. The Method according to claim 6, wherein before this heating a pre-heating of the container to a temperature in the range of 80-200° C. takes place, in particular in a heating tunnel, which is arranged in an inlet to the plasma chamber.

12. The Method according to claim 6, wherein following the method steps a coating of the container interior with a barrier layer and then a coating with silicon oxide is effected and subsequently the container is hot-filled with a filling material which is hotter than 50° C., preferably hotter than 70° C., particularly preferably hotter than 90° C.
